(19) United States
(12) Patent Application Publication
(10) Pub. No.: US 2010/0102855 A1
(43) Pub. Date: Apr. 29, 2010

(54) BUFFER DEVICE

(75) Inventor: Hiroki Takahashi, Kawasaki (JP)

Correspondence Address: KATTEN MUCHIN ROSENMAN LLP, 575 MADISON AVENUE, NEW YORK, NY, 10022-2585, US

(73) Assignee: FUJITSU LIMITED, Kawasaki-shi (JP)

(21) Appl. No.: 12/649,638

(22) Filed: Dec. 30, 2009

Related U.S. Application Data
(63) Continuation of application No. PCT/JP2007/065419, filed on Aug. 7, 2007.

(51) Int. Cl. H03B 1/00

(52) U.S. Cl. 327/108

(57) ABSTRACT

In a buffer device a cross couple circuit includes a first power synthesis section in which a source of a first source follower and a drain of a first source-grounded amplifier are connected and a second power synthesis section in which a source of a second source follower and a drain of a second source-grounded amplifier are connected. A first bias circuit adjusts voltage of gates of the first source-grounded amplifier and the second source-grounded amplifier so as to make common-mode voltage of output from the first power synthesis section and output from the second power synthesis section equal to reference voltage. A second bias circuit applies compensation voltage to gates of the first source follower and the second source follower so as to control variation in voltage applied to the gates of the first source follower and the second source follower.

This application is a continuing application, filed under 35 U.S.C. §111(a), of International Application PCT/JP2007/065419, filed on Aug. 7, 2007.

### FIELD

The embodiment discussed herein is related to a buffer device.

### BACKGROUND

In order to realize high gain at constant power supply voltage in analog signal transmission, it is necessary to make input impedance on a load side (load impedance) as high as possible. When an amplification stage is connected to a load, there is a possibility that the input impedance of the load is low and that the output impedance of the amplification stage is high. In such a case, voltage loss occurs because of voltage division and voltage does not propagate correctly from the amplification stage to the load.

Accordingly, if the amplification stage drives a low-impedance load, it is necessary to put a buffer between the amplification stage and the load so that signal voltage loss can be neglected. Usually a source follower (drain-grounded amplification stage) is used as such a buffer.

FIG. 6 illustrates the structure of an ordinary source follower. FIG. 7 illustrates voltage inputted to and outputted from the source follower. In FIG. 7, a vertical axis indicates output signal voltage Vout and a horizontal axis indicates input signal voltage Vin.

With a source follower 100 using an n-MOSFET (Metal Oxide Semiconductor Field Effect Transistor), one end of a resistor Rs and one end of a load L are connected to a source of an FET m0. A drain of the FET m0 is connected to a power source VDD. A signal is inputted from a gate of the FET m0. The other end of the resistor Rs and the other end of the load L are connected to GND.

If the input voltage Vin of a signal inputted to the gate of the FET m0 is lower than threshold voltage Vth of the FET m0, then the FET m0 is in an OFF state. When the input signal voltage Vin exceeds the threshold voltage Vth, the FET m0 goes into an ON state in a saturation region with respect to VDD and an electric current runs through the resistor Rs. When the input voltage Vin increases, source potential follows gate voltage and the load L connected to the source is driven by the input signal.

In the past, the following source follower circuit was proposed. An average of output from two source followers is found. Voltage corresponding to the difference between the average and a reference value is generated. The voltage generated is supplied to wells of transistors of the two source followers to change their threshold voltage. By doing so, a dynamic range becomes wide even if power supply voltage is low (see, for example, Japanese Laid-open Patent Publication No. 2006-13631 (paragraphs [0016]-[0021] and FIG. 1)).

A source follower has the following characteristics. The amplification factor is approximately one (amplification is not performed). Input impedance is high and output impedance is low. (High input impedance reduces the influence of the use of the circuit and low output impedance enables the driving of more loads.) Source followers are widely used in analog amplifiers.

However, the higher an input signal frequency becomes, the heavier a driving load becomes. Accordingly, if an idling current is weak, the waveform of the output signal voltage Vout on a negative side is clipped and distortion occurs.

FIG. 8 is a view for describing why an increase in the frequency of an input signal leads to a heavy driving load. A signal source is connected to one end of a load L and the other end of the load L is connected to GND. An increase in the frequency of a signal outputted from the signal source causes an increase in the parasitic capacitance of a parallel parasitic capacitor C on a line by which the signal source is connected to the load L, and the influence of a capacitive reactance component cannot be neglected. Therefore, the input impedance of the load L drops and a driving load becomes heavier.

FIG. 9 illustrates how a waveform is clipped. A vertical axis indicates output signal voltage Vout and a horizontal axis indicates time. Though a load becomes heavier and input impedance is low, an idling current of a source follower is weak. In this case, an electric current which is sufficient to drive the load does not flow to the load side, so the negative side of the output signal voltage Vout is clipped (if a p-MOSFET is used, the positive side of a waveform is clipped). If the load becomes heavier, the amplitude of the entire output waveform decreases in addition to the clipping.

Accordingly, in order to secure a desired output dynamic range (desired output amplitude) at high frequencies, it is necessary to increase an electric current which flows through the source follower. This increases current consumption.

In order to obtain sufficient driving capability at high frequencies, it is necessary to increase current consumption. However, even if current consumption is increased, stability is not achieved. The reason for this is as follows. From the viewpoint of the structure of a conventional source follower, variation in the physical parameters of an FET caused by, for example, environmental conditions (including manufacturing process conditions and temperature conditions) has a direct influence on DC voltage outputted from the source follower or the amplitude of output from the source follower. Furthermore, there are many cases where stable DC voltage is needed as a condition for input to a circuit to which a high-frequency circuit in particular is connected. Accordingly, if a source follower having the conventional structure is used, stable operation cannot be realized in the entire circuit.

### SUMMARY

According to one aspect of the embodiment, a buffer device for driving a load by an analog signal includes a cross couple circuit including a first power synthesis section in which a source of a first source follower, a drain of a first source-grounded amplifier, and an inverting output terminal are connected and a second power synthesis section in which a source of a second source follower, a drain of a second source-grounded amplifier, and a non-inverting output terminal are connected, a gate of the first source follower, a gate of the second source-grounded amplifier, and an inverting input terminal being connected, a gate of the second source follower, a gate of the first source-grounded amplifier, and a non-inverting input terminal being connected; a first bias circuit which adjusts voltage of the gates of the first source-grounded amplifier and the second source-grounded amplifier so as to make common-mode voltage of output from the first power synthesis section and output from the second power synthesis section equal to reference voltage; and a second bias circuit which applies compensation voltage to the gates of the first source follower and the second source follower so as to control variation in voltage applied to the gates of the first source follower and the second source follower.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWING(S)

FIG. 1 is a view for describing the principles underlying a buffer device;

FIG. 2 illustrates the structure of the buffer device;

FIG. 3 illustrates frequency characteristics;

FIG. 4 illustrates the waveforms of output;

FIG. 5 illustrates input-output characteristics;

FIG. 6 illustrates the structure of an ordinary source follower;

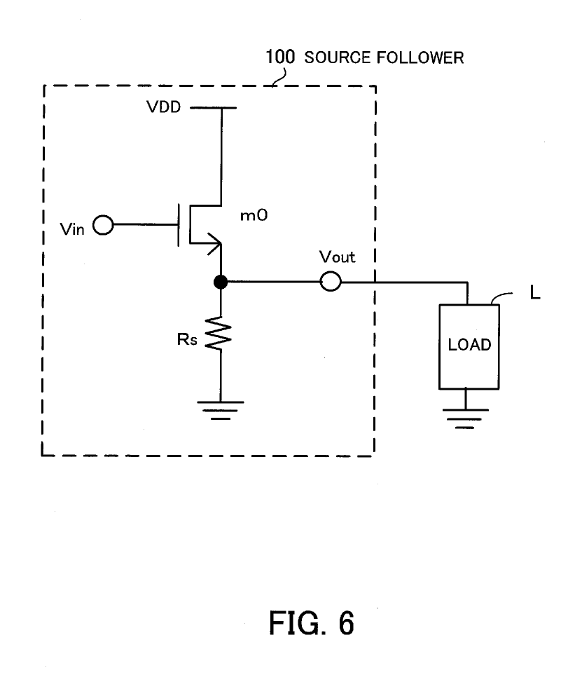

FIG. 7 illustrates voltage inputted to and outputted from the source follower;

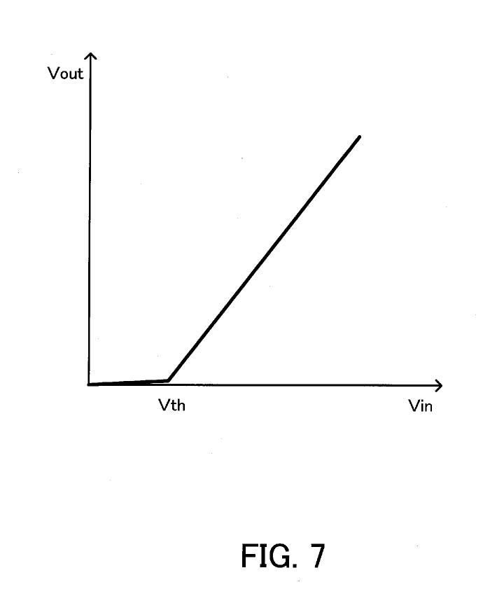

FIG. 8 is a view for describing why an increase in the frequency of an input signal leads to a heavy driving load; and

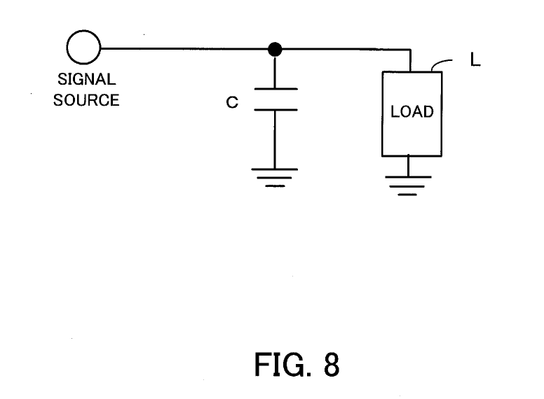

FIG. 9 illustrates how a waveform is clipped.

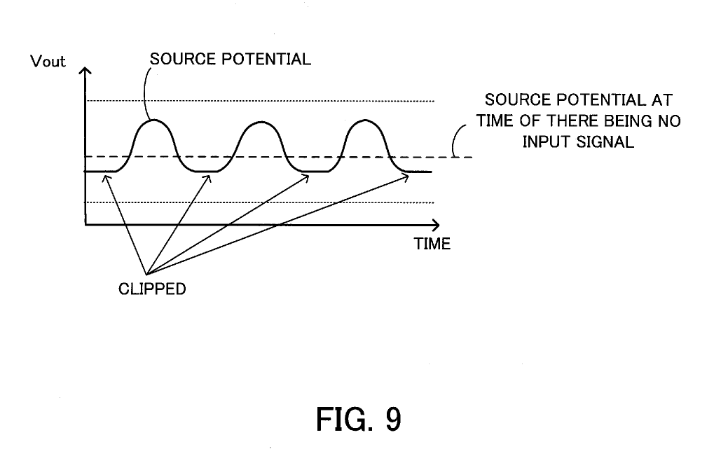

### DESCRIPTION OF EMBODIMENT(S)

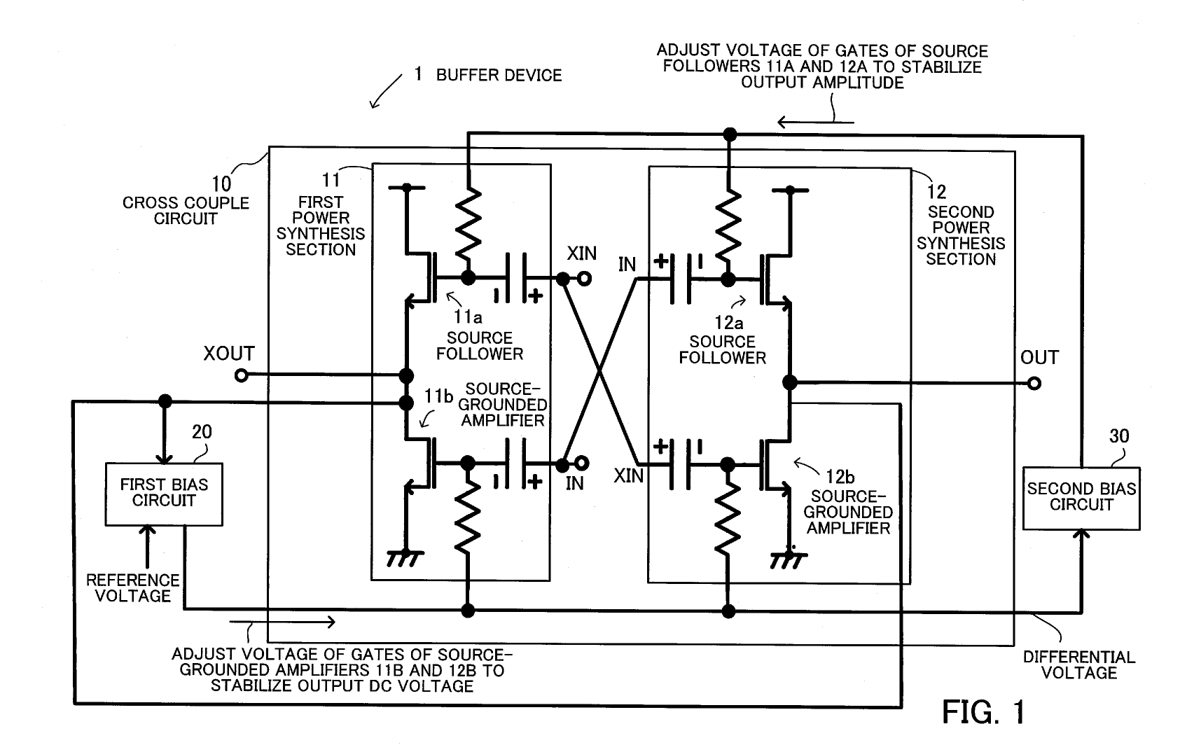

An embodiment of the present invention will now be described with reference to the accompanying drawings. FIG. 1 is a view for describing the principles underlying a buffer device. A buffer device 1 includes a cross couple circuit 10, a first bias circuit 20, and a second bias circuit 30. The buffer device 1 drives a load by a high-frequency analog signal and has two inputs and two outputs.

The cross couple circuit 10 includes a first power synthesis section 11 and a second power synthesis section 12. The first power synthesis section 11 includes a source follower (first source follower) 11a and a source-grounded amplifier (first source-grounded amplifier) 11b. The second power synthesis section 12 includes a source follower (second source follower) 12a and a source-grounded amplifier (second source-grounded amplifier) 12b.

In the first power synthesis section 11a source of the source follower 11a, a drain of the source-grounded amplifier 11b, and an inverting output terminal XOUT are connected. In the second power synthesis section 12 a source of the source follower 12a, a drain of the source-grounded amplifier 12b, and a non-inverting output terminal OUT are connected.

In addition, a gate of the source follower 11a, a gate of the source-grounded amplifier 12b, and an inverting input terminal XIN are connected. A gate of the source follower 12a, a gate of the source-grounded amplifier 11b, and a non-inverting input terminal IN are connected.

The first bias circuit 20 adjusts the voltage (gate-source voltage Vgs) of the gates of the source-grounded amplifier 11b and the source-grounded amplifier 12b so as to make common-mode voltage of output from the first power synthesis section 11 and output from the second power synthesis section 12 equal to reference voltage.

The second bias circuit 30 applies compensation voltage to the gates of the source follower 11a and the source follower 12a so as to control variations in voltage applied to the gates of the source follower 11a and the source follower 12a.

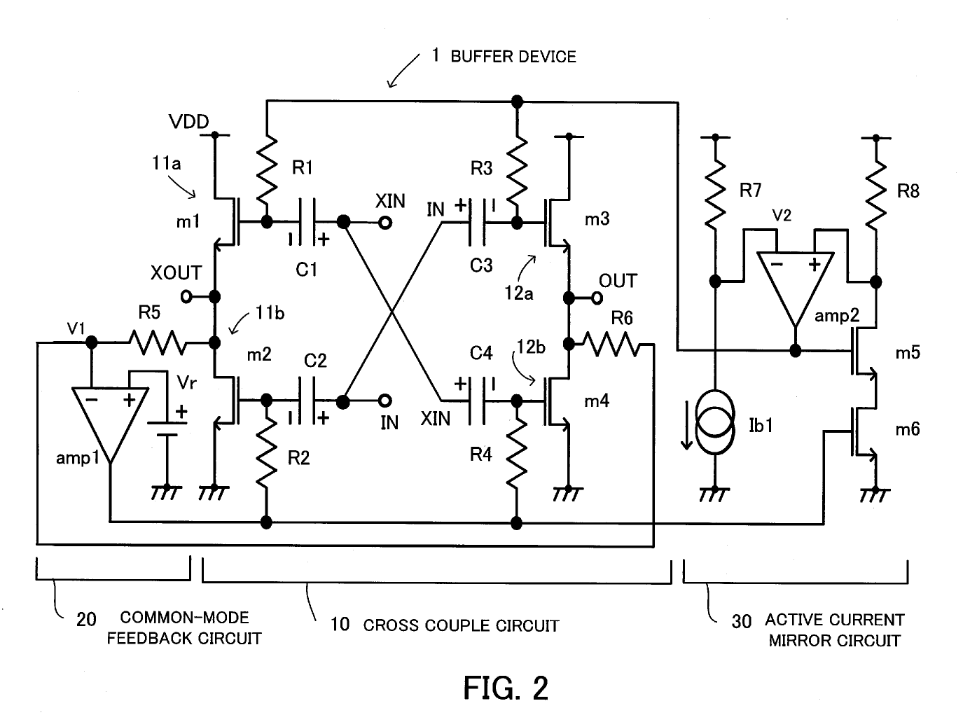

The concrete circuit structure of the buffer device 1 will now be described. FIG. 2 illustrates the structure of the buffer device 1. Hereinafter the first bias circuit 20 and the second bias circuit 30 will be referred to as a common-mode feedback circuit 20 and an active current mirror circuit 30 respectively.

The source follower 11a includes a resistor R1, a condenser C1, and an FET m1. The source-grounded amplifier 11b includes a resistor R2, a condenser C2, and an FET m2. The source follower 12a includes a resistor R3, a condenser C3, and an FET m3. The source-grounded amplifier 12b includes a resistor R4, a condenser C4, and an FET m4.

The common-mode feedback circuit 20 includes resistors R5 and R6, a reference voltage source Vr, and a differential amplifier amp1. The active current mirror circuit 30 includes a resistor R7 (control resistor), a resistor R8 (controlled resistor), a differential amplifier amp2, a constant-current source Ib1, an FET m5 (first transistor), and an FET m6 (second transistor).

How the above elements are connected will now be described. The inverting input terminal XIN is connected to one end of the condenser C1 and one end of the condenser C4. The non-inverting input terminal IN is connected to one end of the condenser C2 and one end of the condenser C3.

The other end of the condenser C1 is connected to one end of the resistor R1 and a gate of the FET m1. The other end of the condenser C2 is connected to one end of the resistor R2 and a gate of the FET m2. The other end of the condenser C3 is connected to one end of the resistor R3 and a gate of the FET m3. The other end of the condenser C4 is connected to one end of the resistor R4 and a gate of the FET m4.

The inverting output terminal XOUT is connected to a source of the FET m1, one end of the resistor R5, and a drain of the FET m2. A drain of the FET m1 is connected to a power source VDD. A source of the FET m2 is connected to GND.

The non-inverting output terminal OUT is connected to a source of the FET m3, one end of the resistor R6, and a drain of the FET m4. A drain of the FET m3 is connected to the power source VDD. A source of the FET m4 is connected to GND.

An input terminal (−) of the differential amplifier amp1 is connected to the other end of the resistor R5 and the other end of the resistor R6. An input terminal (+) of the differential amplifier amp1 is connected to the reference voltage source Vr. An output terminal of the differential amplifier amp1 is connected to the other end of the resistor R2, the other end of the resistor R4, and a gate of the FET m6.

One end of the resistor R7 is connected to the power source VDD. The other end of the resistor R7 is connected to one end of the constant-current source Ib1 and an input terminal (−) of the differential amplifier amp2. One end of the resistor R8 is connected to the power source VDD. The other end of the resistor R8 is connected to an input terminal (+) of the differential amplifier amp2 and a drain of the FET m5.

A source of the FET m5 is connected to a drain of the FET m6 and a source of the FET m6 is connected to GND. An output terminal of the differential amplifier amp2 is connected to a gate of the FET m5, the other end of the resistor R1, and the other end of the resistor R3.

Operation will now be described. In the cross couple circuit 10, an inverted input signal inputted from the inverting input terminal XIN is DC-cut by the condenser C1 and is inputted to the gate of the FET m1 of the source follower 11a. At this time the inverted input signal is biased via the bias resistor R1 by a signal sent from the active current mirror circuit 30. In addition, the inverted input signal is DC-cut by the condenser C4 and is inputted to the gate of the FET m4 of the source-grounded amplifier 12b. At this time the inverted input signal is biased via the bias resistor R4 by a signal sent from the common-mode feedback circuit 20.

A non-inverted input signal inputted from the non-inverting input terminal IN is DC-cut by the condenser C2 and is inputted to the gate of the FET m2 of the source-grounded amplifier lib. At this time the non-inverted input signal is biased via the bias resistor R2 by a signal sent from the common-mode feedback circuit 20. In addition, the non-inverted input signal is DC-cut by the condenser C3 and is inputted to the gate of the FET m3 of the source follower 12a. At this time the non-inverted input signal is biased via the bias resistor R3 by a signal sent from the active current mirror circuit 30.

A signal which passes through the source follower 11a and a signal which passes through the source-grounded amplifier 11b are power-synthesized and an inverted output signal is outputted from the inverting output terminal XOUT. A signal which passes through the source follower 12a and a signal which passes through the source-grounded amplifier 12b are power-synthesized and a non-inverted output signal is outputted from the non-inverting output terminal OUT.

In the common-mode feedback circuit 20, common-mode DC voltage (average) V1 of the non-inverted output signal and the inverted output signal obtained by the resistance ratio of the monitor resistor R5 to the monitor resistor R6 is applied to the input terminal (−) of the differential amplifier amp1. The reference voltage source Vr is connected to the input terminal (+) of the differential amplifier amp1. As a result, the differential amplifier amp1 outputs a differential voltage between the common-mode voltage V1 and the reference voltage Vr.

The differential voltage is fed back to the source-grounded amplifier 11b via the resistor R2 and is fed back to the source-grounded amplifier 12b via the resistor R4. The voltage of the gates of the source-grounded amplifier 11b and the source-grounded amplifier 12b is adjusted so as to make the common-mode voltage V1 equal to the reference voltage Vr. By doing so, the DC voltage of the non-inverted output signal and the inverted output signal is stabilized. (Feedback performed for making the average of non-inverted signal voltage and inverted signal voltage a predetermined value is refereed to as common-mode feedback.)

In the active current mirror circuit 30, control voltage V2 generated across the control resistor R7 by an electric current which flows through the constant-current source Ib1 is applied to the input terminal (−) of the differential amplifier amp2 and the controlled resistor R8 is connected to the input terminal (+) of the differential amplifier amp2.

The differential amplifier amp2 changes the voltage of the gate of the FET m5 until the control voltage V2 is generated across the controlled resistor R8. At this time an electric current which flows through the resistor R7 flows through the resistor R8 by mirroring (A technique by which voltage generated across a control resistor is also generated across a controlled resistor and by which the same electric current flows through the controlled resistor is referred to as current mirroring.)

The differential voltage outputted from the differential amplifier amp1 is applied to the gate of the FET m6, so the FET m5 (active current mirror circuit 30) operates in concert with the common-mode feedback circuit 20.

Voltage outputted from the differential amplifier amp2 is applied to the gates of the source follower 11a and the source follower 12a as compensation voltage. This stabilizes the amplitude of the non-inverted output signal and the inverted output signal.

Transconductance gm of a MOSFET is defined by the amount of a change in drain current obtained at the time of changing gate voltage by a minute amount (gm=ΔId/ΔVgs), and depends on the gate voltage. In the active current mirror circuit 30, the compensation voltage is generated on the basis of the constant-current source Ib1 and is applied to the gates of the source follower 11a and the source follower 12a. By doing so, even if the environment changes, optimum transconductance gm is obtained. As a result, variation in the amplitude of output is controlled.

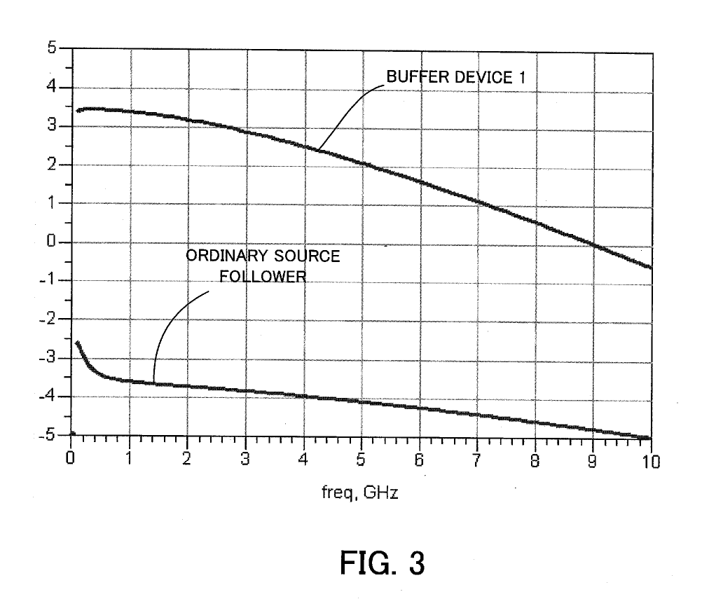

A comparison made between the characteristics of the buffer device 1 and an ordinary source follower simulated under the conditions of the same electric current and the same driven load will now be described. FIG. 3 illustrates frequency characteristics. In FIG. 3, a vertical axis indicates a forward transmission characteristic (S21) and a horizontal axis indicates a frequency (GHz). With an ordinary source follower, gain is below 0 and attenuation is performed. With the buffer device 1, however, gain is obtained even at high frequencies.

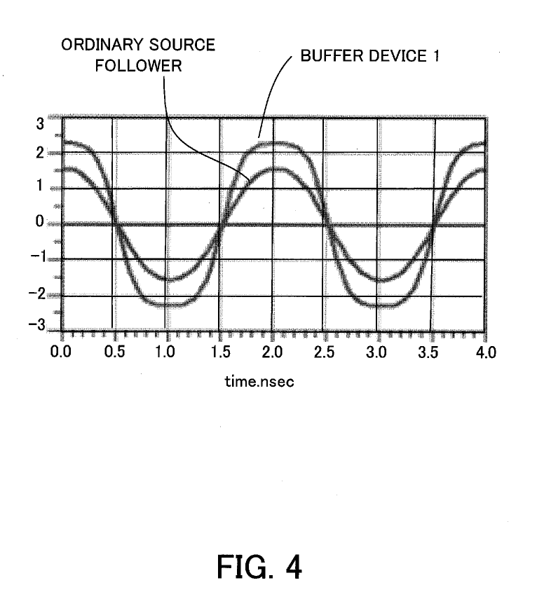

FIG. 4 illustrates the waveforms of output. In FIG. 4, a vertical axis indicates voltage and a horizontal axis indicates time. FIG. 4 illustrates the waveforms of output from the buffer device 1 and the ordinary source follower obtained at a power supply voltage of 2.9 volts

With the buffer device 1, as can be seen from FIG. 4, the amplitude of output can be increased to a value near the power supply voltage. Compared with the ordinary source follower, driving efficiency is very high. With the buffer device 1, a clipping point becomes higher. Therefore, even if the amplitude of output is increased to a value near the power supply voltage, the waveform of the output is not clipped.

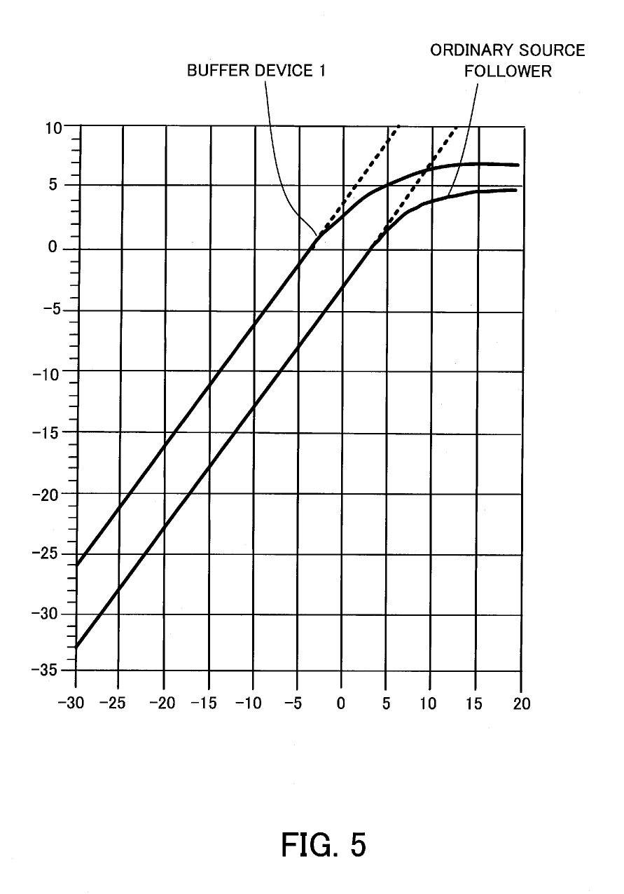

FIG. 5 illustrates input-output characteristics. In FIG. 5, a vertical axis indicates output signal power (dBm) and a horizontal axis indicates input signal power (dBm). With the buffer device 1, constant power (CP) is obtained. Compared with the ordinary source follower, high power can be obtained.

As has been described in the foregoing, with the buffer device 1 the common-mode feedback circuit 20 compensates for and stabilizes output DC voltage and the active current mirror circuit 30 compensates for and stabilizes output amplitude. By doing so, even if environmental conditions and the like change, an output signal can be stabilized. Compared with conventional source followers, a great load driving capability can be realized even at high frequencies.

The buffer device according to the present embodiment includes the cross couple circuit including the first power synthesis section in which the source of the first source follower and the drain of the first source-grounded amplifier are connected and the second power synthesis section in which the source of the second source follower and the drain of the second source-grounded amplifier are connected, the first bias circuit which adjusts voltage of the gates of the first source-grounded amplifier and the second source-grounded amplifier so as to make common-mode voltage of output from the first power synthesis section and output from the second power synthesis section equal to reference voltage, and the second bias circuit which applies compensation voltage to the gates of the first source follower and the second source follower so as to control variation in voltage applied to the gates of the first source follower and the second source follower. As a result, variation in output DC voltage or output amplitude which is apt to change according to environmental conditions and the like is controlled and an output signal is stabilized. Accordingly, load driving capability can be improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention has (have) been described in detail, it should be understood that various changes, substitutions, and alterations could be made hereto without departing from the spirit and scope of the invention.

What is claimed is:

1. A buffer device for driving a load by an analog signal, the device comprising:
a cross couple circuit including a first power synthesis section in which a source of a first source follower, a drain of a first source-grounded amplifier, and an inverting output terminal are connected and a second power synthesis section in which a source of a second source follower, a drain of a second source-grounded amplifier, and a non-inverting output terminal are connected, a gate of the first source follower, a gate of the second source-grounded amplifier, and an inverting input terminal being connected, a gate of the second source follower, a gate of the first source-grounded amplifier, and a non-inverting input terminal being connected;
a first bias circuit which adjusts voltage of the gates of the first source-grounded amplifier and the second source-grounded amplifier so as to make common-mode voltage of output from the first power synthesis section and output from the second power synthesis section equal to reference voltage; and
a second bias circuit which applies compensation voltage to the gates of the first source follower and the second source follower so as to control variation in voltage applied to the gates of the first source follower and the second source follower.

2. The buffer device according to claim 1, wherein the first bias circuit finds a differential voltage between the common-mode voltage and the reference voltage, applies the differential voltage to the gates of the first source-grounded amplifier and the second source-grounded amplifier, adjusts the voltage of the gates of the first source-grounded amplifier and the second source-grounded amplifier so as to make the common-mode voltage equal to the reference voltage, and stabilizes DC voltage outputted from the first power synthesis section and the second power synthesis section.

3. The buffer device according to claim 2, wherein:
the second bias circuit includes a constant-current source, a differential amplifier, a control resistor, a controlled resistor, a first transistor, and a second transistor;
one end of the control resistor is connected to a power source, an other end of the control resistor is connected to one input terminal of the differential amplifier and one end of the constant-current source, and an other end of the constant-current source is connected to GND;
one end of the controlled resistor is connected to the power source and an other end of the controlled resistor is connected to an other input terminal of the differential amplifier and a drain of the first transistor;
an output terminal of the differential amplifier is connected to the gate of the first source follower, the gate of the second source follower, and a gate of the first transistor;
a drain of the second transistor is connected to a source of the first transistor, the differential voltage outputted from the first bias circuit is applied to a gate of the second transistor, and a source of the second transistor is connected to GND;
control voltage which is generated across the control resistor by an electric current that flows through the constant-current source and which is applied to the one input terminal of the differential amplifier is also generated across the controlled resistor connected to the other input terminal of the differential amplifier, and voltage outputted from the differential amplifier changes voltage of the gate of the first transistor so that the electric current flows through the controlled resistor by mirroring;
applying the differential voltage to the gate of the second transistor drives the first transistor in concert with the first bias circuit; and
amplitude of the output from the first power synthesis section and the output from the second power synthesis section is stabilized by applying the voltage outputted from the differential amplifier to the gates of the first source follower and the second source follower as the compensation voltage.
